(19) United States
(12) Patent Application Publication
(10) Pub. No.: US 2024/0291210 A1
(43) Pub. Date: Aug. 29, 2024

(54) CONNECTOR ASSEMBLY

(71) Applicant: Molex, LLC, Lisle, IL (US)

(72) Inventors: Chao-Hung Hsu, New Taipei City (TW); Tsai-Hui Chien, New Taipei City (TW)

(21) Appl. No.: 18/443,359

(22) Filed: Feb. 16, 2024

(30) Foreign Application Priority Data
Feb. 17, 2023 (CN) 202320270571.1

(51) Int. Cl. H01R 13/6594; H01R 12/71; H01R 13/627; H01R 13/6581

(52) U.S. Cl. CPC H01R 13/6594; H01R 12/716; H01R 13/6273; H01R 13/6581

(57) ABSTRACT

A connector assembly includes a guiding shield cage, a light guide member and a light guide member assembling construction. The guiding shield cage includes a top wall, a side wall, a bottom wall, and a supporting plate which extends from the bottom wall and is positioned at an outer side of the side wall. The light guide member is provided at the outer side of the side wall of the guiding shield cage and is upwardly supported by the supporting plate. The light guide member assembling construction includes a first latching construction and a second latching construction, the first latching construction is provided between the light guide member and the supporting plate which extends from the bottom wall, the second latching construction is provided between the light guide member and the top wall.

### TECHNICAL FIELD

The present disclosure relates to a connector assembly, and particularly relates to a connector assembly which has a light guide member.

### BACKGROUND

Chinese patent document CN110364871B (corresponding to United State patent U.S. Pat. No. 10,950,983B2) discloses a side wall of a cage and light guiding pipes are formed thereon with a latching structure, the latching structure includes a first latching structure which is adapted to position the light guiding pipes in a vertical direction and a second latching structure which is adapted to position the light guiding pipes in a horizontal direction; the first latching structure includes a first connecting post which extends along the horizontal direction and is connected between the two corresponding adjacent light guiding pipes and a first latching member which has a first C-shaped latching groove adapted to latch over the first connecting post; the second latching structure includes a second connecting post which extends along the vertical direction and is connected between the two corresponding adjacent light guiding pipes and a second latching member which has a second C-shaped latching groove adapted to latch over the second connecting post.

However, the first latching member and the second latching member are stamped members which are formed by stamping the side wall of the cage, that is, it needs to stamp apertures on the side wall of the cage to form the latching members, these apertures will lower an electromagnetic interference suppressing effect of the cage. In addition, the latching member and the connecting post latch with each other therebetween only by means of the C-shaped latching groove, an assembling structure is not sufficient in strengthen and thus is not firm. Moreover, the light guiding pipes need to be sideward assembled or detached, a space needs to be reserved at a side surface of the cage, when it is applied to a combination that guiding shield cages are arranged side by side, only it needs increase a sideward arrangement pitch of the guiding shield cages, can the light guiding pipes have a sufficient space to be sideward assembled or detached; even if the light guiding pipes are assembled before the guiding shield cages are arranged side by side in some cases, such an assembling structure will still make that the corresponding light guiding pipes cannot be detached after all the assembling operations are completed.

### SUMMARY

Therefore, an object of the present disclosure is to provide a connector assembly which can improve at least one problem of prior art.

Accordingly, in some embodiments, a connector assembly of the present disclosure comprises a guiding shield cage, a light guide member and a light guide member assembling construction. The guiding shield cage comprises a top wall, a side wall, a bottom wall, and a supporting plate which extends from the bottom wall and is positioned at an outer side of the side wall. The light guide member is provided at the outer side of the side wall of the guiding shield cage and is upwardly supported by the supporting plate. The light guide member assembling construction comprises a first latching construction and a second latching construction, the first latching construction is provided between the light guide member and the supporting plate which extends from the bottom wall, the second latching construction is provided between the light guide member and the top wall.

In some embodiments, the first latching construction comprises the supporting plate and a first latching block, the supporting plate is a plate tab which integrally extends out of the side plate and is positioned at the outer side of the side wall, a plate surface of the supporting plate faces up; the first latching block is constructed on the light guide member, the first latching block latches over the supporting plate; the second latching construction comprises a supporting protrude piece and a second latching block, the supporting protrude piece is integrally constructed out of the top wall, a piece surface of the supporting protrude piece faces a side surface of the guiding shield cage, the second latching block is constructed on the light guide member, the second latching block snaps to the supporting protrude piece.

In some embodiments, the supporting plate has an opened hole, the first latching block has a latching groove which is opened toward the rear, the first latching block passes through the opened hole of the supporting plate, so that the latching groove is capable of being pushed rearwardly and latching over the supporting plate.

In some embodiments, the supporting plate integrally extends out of the side plate sideward.

In some embodiments, the supporting protrude piece has a latching notch which is in form of necking and is opened upwardly, the second latching block has a necking portion, the necking portion of the second latching block downwardly squeezes into and snaps in the latching notch of the supporting protrude piece.

In some embodiments, the light guide member comprises a plurality of light guiding pipes and a first connecting rod connected between the light guiding pipes, the first latching block extends downwardly from the first connecting rod, the first latching block has a lower latching block and the latching groove which is constituted by the lower latching block and the first connecting rod and is positioned between the lower latching block and the first connecting rod, the first connecting rod is upwardly supported by the supporting plate, the side plate upwardly supports the light guide member via the supporting plate and the first connecting rod.

In some embodiments, the light guide member further comprises a second connecting rod which is connected between the light guiding pipes, the second latching block extends inwardly from the second connecting rod t and extend toward the guiding shield cage.

In some embodiments, the guiding shield cage comprises an upper shell and a lower shell, the upper shell comprises the top wall and two side walls, the lower shell comprises the bottom wall and two side plates which extends upwardly from two sides of the bottom wall respectively, the two side plates are respectively positioned at outer side surfaces of the two side walls and respectively latch to the two side walls.

In some embodiments, the light guide member is provided at the outer side of one corresponding side wall of the two side walls and is upwardly supported by one corresponding side plate of the two side plates, the light guide member comprises a plurality of light guiding pipes and a plurality of connecting rods, the plurality of light guiding pipes are sequentially arranged from up to down in a plane which is parallel to the one corresponding side wall and are spaced apart from each other, each light guiding pipe has a forward extending segment which is positioned in the front of the light guiding pipe and extends forwardly, a downward extending segment which is positioned at the rear of the light guiding pipe and extend downwardly, and a bending segment which is positioned between the forward extending segment and the downward extending segment, the plurality of light guiding pipes are therebetween connected with each other via the plurality of connecting rods, the plurality of connecting rods comprises a first connecting rod which extends front and rear and is connected between the downward extending segments and a second connecting rod which extends up and down and is connected between the forward extending segments, the first latching block extends downwardly from the first connecting rod, the second latching block extends inwardly from the second connecting rod and extends toward the guiding shield cage.

In the present disclosure, the corresponding side plate which extends from the bottom wall is capable of upwardly supporting the light guide member, and the light guide member is fixed on the corresponding side plate and the top wall at the same time via the light guide member assembling construction, an operation in assembling is easy and the light guiding pipe can be stably and reliably fixed. In addition, the light guiding pipe is provided at the outer side of the corresponding side wall and is capable of being assembled and detached front and rear and up and down, so that a space occupied sideward can be saved. Particularly in an application that a plurality of connector assemblies are arranged side by side, the spaces which are saved sideward are capable of making the guiding shield cages of the plurality of connector assemblies arranged compactly, and it can avoid the corresponding light guiding pipes cannot being detached and assembled after arrangement provision of the guiding shield cages of the plurality of connector assembly are completed. Moreover, the corresponding side wall of the guiding shield cage does not need to be provided with a construction which is used to assemble the light guiding pipe, so it does not need to add an aperture in the corresponding side wall for such a construction, therefore it can further increase the electromagnetic interference suppressing effect of the guiding shield cage.

### BRIEF DESCRIPTION OF THE DRAWINGS

Other features and effects of the present disclosure will be apparent from an embodiment with reference to the drawings, in which:

FIG. 1 is a perspective view of an embodiment of a connector assembly of the present disclosure and a pluggable module;

FIG. 2 is a perspective exploded view of the embodiment;

FIG. 3 is a further perspective exploded view of the embodiment;

FIG. 4 is a perspective view of a light guide member of the embodiment;

FIG. 5 is a partially enlarged perspective view of a lower shell of a guiding shield cage of the embodiment of FIG. 3, which is used to illustrate a supporting plate formed to extend from a side plate of the guiding shield cage;

FIG. 6 is a partially enlarged perspective view of the light guide member of the embodiment, which is used to illustrate a first latching block constructed to the light guide member;

FIG. 7 is another partially enlarged perspective view of the light guide member of the embodiment, which is used to illustrate a second latching block constructed to the light guide member;

FIG. 8 is a partial perspective view of the guiding shield cage and the light guide member of the embodiment, in which the first latching block does not latch to the supporting plate;

FIG. 9 is a partially enlarged perspective view of the guiding shield cage and the light guide member of the embodiment, in which the first latching block latches to the supporting plate;

FIG. 10 is a perspective view of the guiding shield cage and the light guide member of the embodiment, in which the second latching block does not snap to a supporting protrude piece constructed out of a top wall of the guiding shield cage;

FIG. 11 is a perspective view of the guiding shield cage and the light guide member of the embodiment, in which the second latching block snaps to the supporting protrude piece constructed out of the top wall of the guiding shield cage.

Reference numerals are presented as follows.
100 connector assembly
1 guiding shield cage
1a upper shell
1b lower shell
11 top wall
111 window
112 guiding portion
113 stopping portion
12 bottom wall
13 side wall
131 locking block
132 dovetail recess
133 lock block
134 inward extending elastic piece
14 side plate
141 locking hole
15 rear wall
16 mating channel
161 front end inserting port
162 bottom opening
17 inserting leg
18 dovetail protrusion
19 ground member
191 elastic portion
2 receptacle connector
21 housing
211 mating slot
22 terminal
221 contact portion
3 heat sink
31 base plate
32 thermal coupling portion
33 heat dissipating fin
34 recessed groove
4 clip
41 lock portion
411 lock hole
42 spring portion
421 connecting arm
5 light guide member
51 light guiding pipe
511 forward extending segment
511a light outputting end
512 downward extending segment
512a light inputting end
513 bending segment
52 connecting rod
521 first connecting rod
522 second connecting rod
6 light guide member assembling construction
61 first latching construction
611 supporting plate
611a opened hole
612 first latching block
612a lower latching block
612b latching groove
62 second latching construction
621 supporting protrude piece
621a latching notch
622 second latching block
622a necking portion
200 pluggable module
201 shell member
201a inserting portion
201b locking recessed groove
201c guiding groove structure
201d aligning structure
202 mating circuit board
203 cable
204 locking release member
D1 up-down direction
D2 left-right direction
D3 front-rear direction

### DETAILED DESCRIPTION

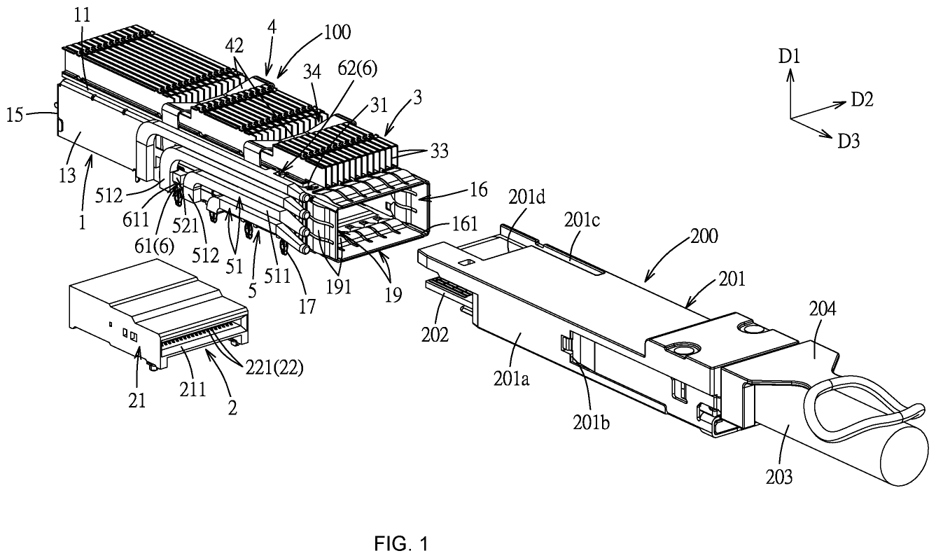

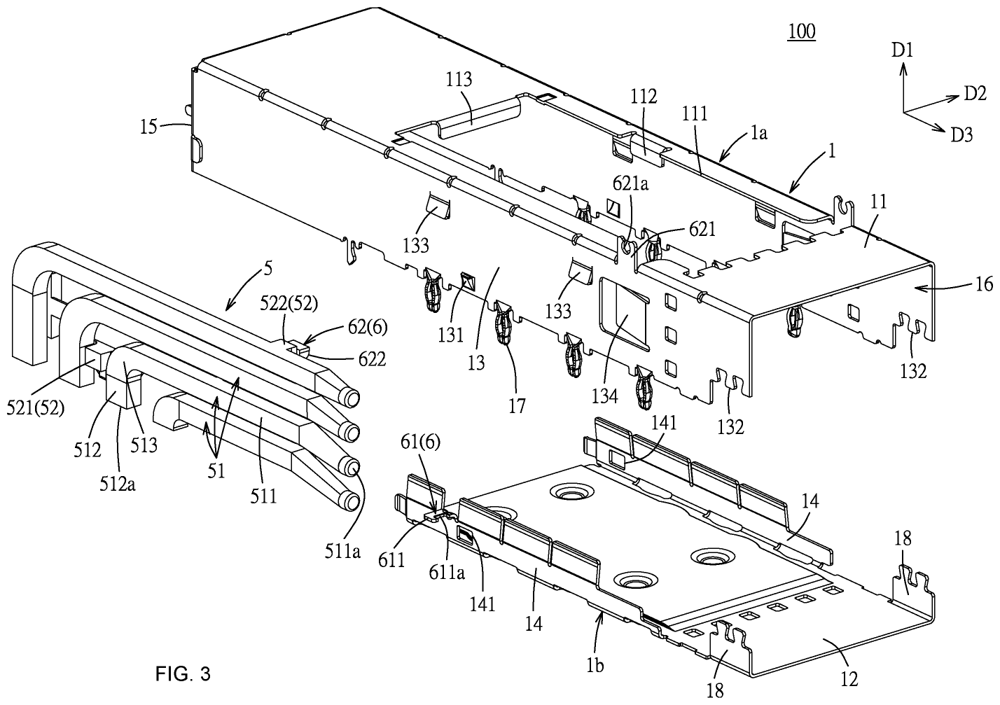

Referring to FIG. 1 to FIG. 3, an embodiment of a connector assembly 100 of the present disclosure is adapted to be provided to a circuit board (not shown) and is adapted to mate with a pluggable module 200. The pluggable module 200 has a shell member 201, a mating circuit board 202 and a cable 203. The shell member 201 has an inserting portion 201a, the mating circuit board 202 is provided to a front end of the inserting portion 201a, the cable 203 is provided to a rear end of the shell member 201 and is electrically connected to the mating circuit board 202. The connector assembly 100 includes a guiding shield cage 1, a receptacle connector 2, a heat sink 3, a clip 4, a light guide member 5, and a light guide member assembling construction 6.

The guiding shield cage 1 is for example formed by processing, such as stamping and bending, a metal thin plate via a mold, the guiding shield cage 1 is used to be provided to the circuit board. The guiding shield cage 1 has a top wall 11 and a bottom wall 12 which are spaced apart from each other along an up-down direction DI (a direction to which an arrow points is up, and an opposite direction is down), two side walls 13 which are spaced apart from each other along a left-right direction D2 (a direction to which an arrow points is right, and an opposite direction is left), two side plates 14 which extend from the bottom wall 12 and are respectively positioned to outer sides of the two side walls 13, a rear wall 15 which is positioned to a rear end of the guiding shield cage 1 along a front-rear direction D3 (a direction to which an arrow points is front, and an opposite direction is rear), and a mating channel 16 which is positioned inside the guiding shield cage 1. Lower edges of the two side walls 13 are constructed with a plurality of inserting legs 17 which extend downwardly and are adapted to be fixed on the circuit board and/or be connected to a ground trace (not shown). The mating channel 16 has a front end inserting port 161 which is toward the front and allows the inserting portion 201a of the pluggable module 200 to insert therein and a bottom opening 162 which is positioned at a rear of a bottom portion of the mating channel 16.

In the present embodiment, the guiding shield cage 1 includes an upper shell la and a lower shell 1b which are assembled with each other and construct the mating channel 16. The upper shell 1a has the top wall 11 and the two side walls 13 which are integrally connected with each other, a plurality of locking blocks 131 which are formed to the two side walls 13, are close to the lower edges of the two side walls 13 and protrude outwardly, and two dovetail recesses 132 which are respectively formed to bottom edges of the two side walls 13 close to front ends of the two side walls 13. The lower shell 1b has the bottom wall 12, the two side plates 14 which integrally extend upwardly from two sides of the bottom wall 12 respectively, a plurality of locking holes 141 which are formed to the two side plates 14 and correspond to the plurality of locking blocks 131 of the two side walls 13, and two dovetail protrusions 18 which are integrally formed upwardly from the bottom wall 12 close to a front end of the bottom wall 12 and correspondingly cooperate with the two dovetail recesses 132 of the two side walls 13. The two side plates 14 of the lower shell 1b are respectively positioned at outer side surfaces of the two side walls 13 of the upper shell 1a, the plurality of locking holes 141 of the two side plates 14 respectively latch to the plurality of locking blocks 131 of the two side walls 13, so that the bottom wall 12 of the lower shell 1b is capable of being assembled and engaged with the two side walls 13 of the upper shell 1a.

The top wall 11 of the guiding shield cage I has a window 111 which is communicated with the mating channel 16, a guiding portion 112 which extends downwardly from a rear segment of a side of the window 111 into the mating channel 16, and a stopping portion 113 which extends downwardly from a rear end of the window 111 into the mating channel 16. Each side wall 13 of the guiding shield cage I has two lock blocks 133 which are close to an upper edge of the side wall 13 and an inward extending elastic piece 134 which is positioned in front of the two lock blocks 133.

A periphery of the guiding shield cage 1 positioned at the front end inserting port 161 are assembled with a plurality of ground members 19. In the present embodiment, the guiding shield cage 1 of the connector assembly 100 may be provided to a mounting hole (not shown) of a casing (not shown), each ground member 19 has a plurality of elastic portions 191 which extend rearwardly and are distributed to an outer side and an inner side of the guiding shield cage 1, the clastic portion 191 of the plurality of elastic portions 191 which is positioned at the outer side of the guiding shield cage 1 is used to contact a part of a periphery of the mounting hole of the casing, the elastic portion 191 of the plurality of elastic portions 191 which is positioned at the inner side of the guiding shield cage 1 is used to contact the pluggable module 200.

The receptacle connector 2 is used to be provided on the circuit board, the receptacle connector 2 is received to a rear segment of the mating channel 16 via the bottom opening 162 of the guiding shield cage 1. The receptacle connector 2 has a housing 21 which is insulative and a plurality of terminals 22 which are provided to the housing 21. The housing 21 has a mating slot 211 which allows the mating circuit board 202 of the pluggable module 200 to insert therein. Each terminal 22 has a contact portion 221 which is positioned in the mating slot 211 and a tail portion (not shown) which extends downwardly out of a bottom portion of the housing 21, the tail portions of the plurality of terminals 22 are respectively used to be soldered to pads (not shown) on the circuit board so as to be connected with electrically conductive traces (not shown) on the circuit board.

The inserting portion 201a of the pluggable module 200 has two locking recessed grooves 201b which are respectively positioned at a left side and a right side of the inserting portion 201a, a guiding groove structure 201c which is positioned to a top portion of the front end of the inserting portion 201a, and an aligning structure 201d which is positioned to a top portion of the inserting portion 201a. The inward extending elastic pieces 134 of the two side walls 13 of the guiding shield cage 1 are used to cooperate with the two locking recessed grooves 201b of the pluggable module 200 which inserts into the mating channel 16, so as to generate a locking effect. The guiding portion 112 is used to insert into the guiding groove structure 201c of the pluggable module 200 so as to generate a guiding function. The stopping portion 113 is used to stop the aligning structure 201d of the pluggable module 200 so as to limit an inserting position of the pluggable module 200. In addition, the pluggable module 200 further has a locking release member 204, when the locking release member 204 is pulled, the inward extending elastic piece 134 can be pushed out of the locking recessed groove 201b.

The clip 4 is used to assemble the heat sink 3 to the top wall 11 of the guiding shield cage 1 in a manner that the heat sink 3 is movable up and down. The heat sink 3 has a base plate 31, a thermal coupling portion 32 which is positioned to a bottom portion of the base plate 31 and is capable of extending into the mating channel 16 via the window 111, a plurality of heat dissipating fins 33 which are positioned to a top portion of the base plate 31, and two recessed grooves 34 which are formed among the plurality of heat dissipating fins 33 and extend sideward along the left-right direction D2. Here, although the plurality of heat dissipating fins 33 are a plurality of heat dissipating plates which latch with each other and are provided to a top surface of the base plate 31 by for example welding in the embodiment, in a varied implementing manner, the plurality of heat dissipating fins 33 also may be integrally constructed on the base plate 31.

The thermal coupling portion 32 of the heat sink 3 is used to contact the pluggable module 200 which inserts into the mating channel 16, thereby promoting heat dissipating performance of the heat sink 3. In the present embodiment, the thermal coupling portion 32 includes a thermal conductive pad (not shown) which is positioned to a bottom portion of the thermal coupling portion 32 and is used to contact the pluggable module 200, the thermal conductive pad is capable of filling seams or gaps of contact surfaces to reduce a contact thermal resistance between the contact surfaces, increase heat transfer efficiency. The thermal conductive pad for example may be a thermal interface material, the thermal interface material may be selected from, for example, a combination of materials with performances, such as high thermal conductivity, high flexibility, compressibility, insulation, abrasion resistance, etc. al, and for example, can be a combination of a substrate material and a phase change material

The clip 4 is immovably assembled to the guiding shield cage 1. The clip 4 has two lock portions 41 which are arranged left and right and two spring portions 42 which are connected between the two lock portions 41. Each spring portion 42 has two connecting arms 421 which are respectively positioned at a left end and a right end of the spring portion 42 and obliquely extend upwardly and outwardly, the two connecting arms 421 respectively connect the two lock portions 41. Each lock portion 41 has two lock holes 411 which respectively latch to the two lock blocks 133 of the corresponding side wall 13, the two spring portions 42 are respectively received in the two recessed grooves 34 of the heat sink 3 and downwardly apply elastic acting forces to the heat sink 3.

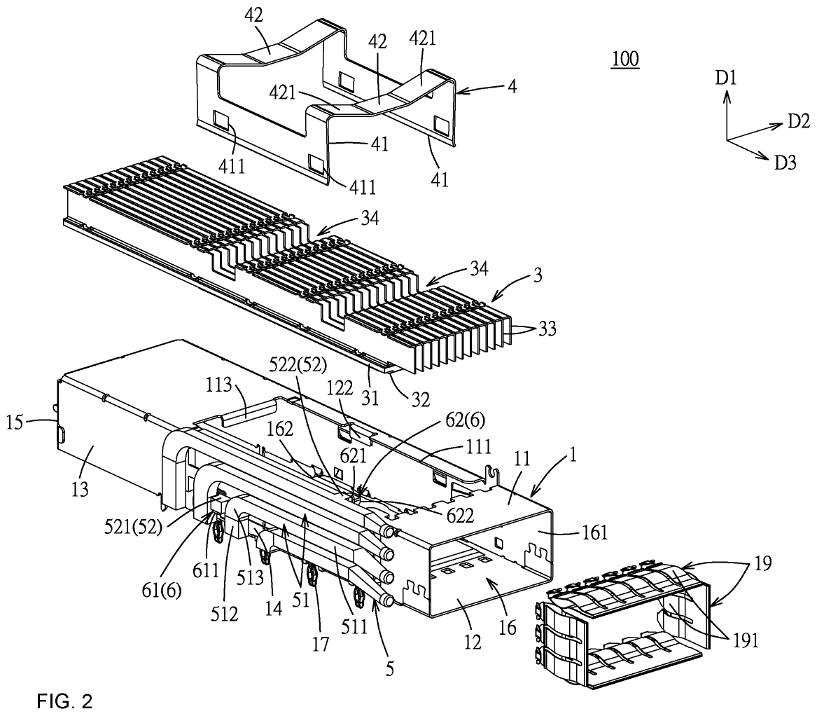

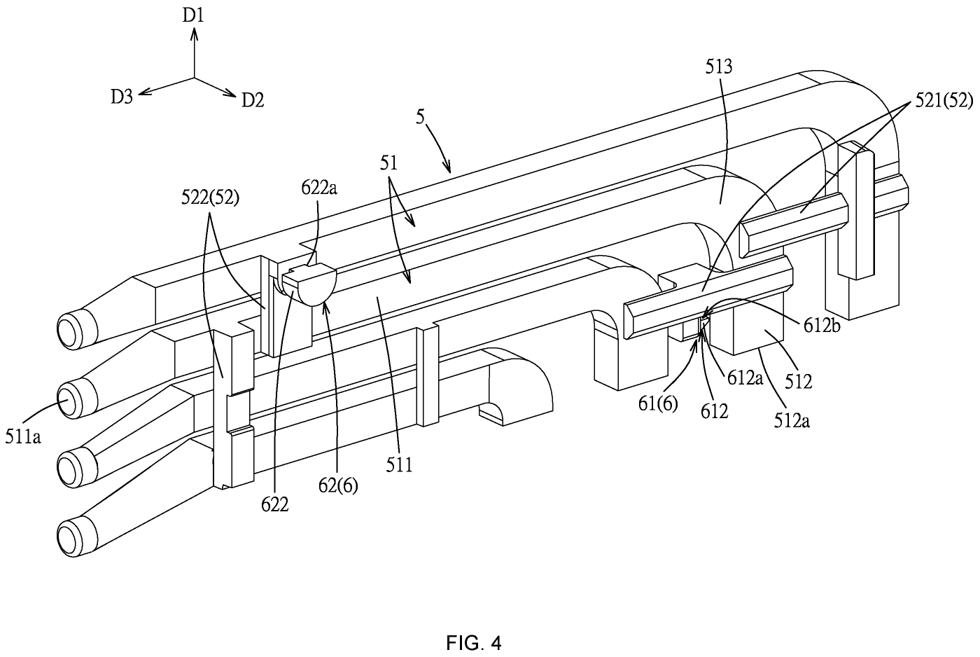

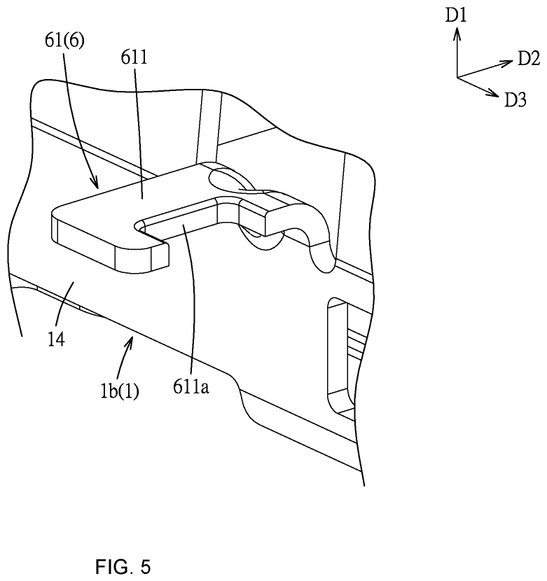

Referring to FIG. 2 to FIG. 5, the light guide member 5 is provided at the outer side of one side wall of the two side walls 13 of the guiding shield cage 1 and is upwardly supported by one of the two side plates 14 which is correspondingly positioned at the same side as the one side wall of the two side walls 13. The light guide member 5 includes a plurality of light guiding pipes 51 and a plurality of connecting rods 52. The plurality of light guiding pipes 51 are sequentially arranged from up to down in a plane which is substantially parallel to the one side wall 13 and are spaced apart from each other, each light guiding pipe 51 has a forward extending segment 511 which is positioned in the front of the light guiding pipe 51 and extends forwardly, a downward extending segment 512 which is positioned at the rear of the light guiding pipe 51 and extends downwardly, and a bending segment 513 which is positioned between the forward extending segment 511 and the downward extending segment 512. A light inputting end 512 at a tip of the downward extending segment 512 of each light guiding pipe 51 is used to face a light emitting member (not shown) on the circuit board and accept a light beam emitted by the light emitting member, and a light outputting end 511a at a tip of the forward extending segment 511 of each light guiding pipe 51 is used to output the light beam of the light emitting member forwardly. The plurality of light guiding pipes 51 are therebetween connected with each other by the plurality of connecting rods 52. The plurality of connecting rods 52 includes a plurality of first connecting rods 521 which extend front and rear and are connected between the downward extending segments 512 of the plurality of light guiding pipes 51, and a plurality of second connecting rods 522 which extend up and down and are connected between the forward extending segments 511 of the plurality of light guiding pipes 51.

The light guide member assembling construction 6 is used to assemble the light guide member 5 to the guiding shield cage 1. The light guide member assembling construction 6 includes a first latching construction 61 and a second latching construction 62. The first latching construction 61 is relatively positioned down and rear, the second latching construction 62 is relatively positioned up and front, in other words, the first latching construction 61 and the second latching construction 62 are respectively at two ends of an oblique direction.

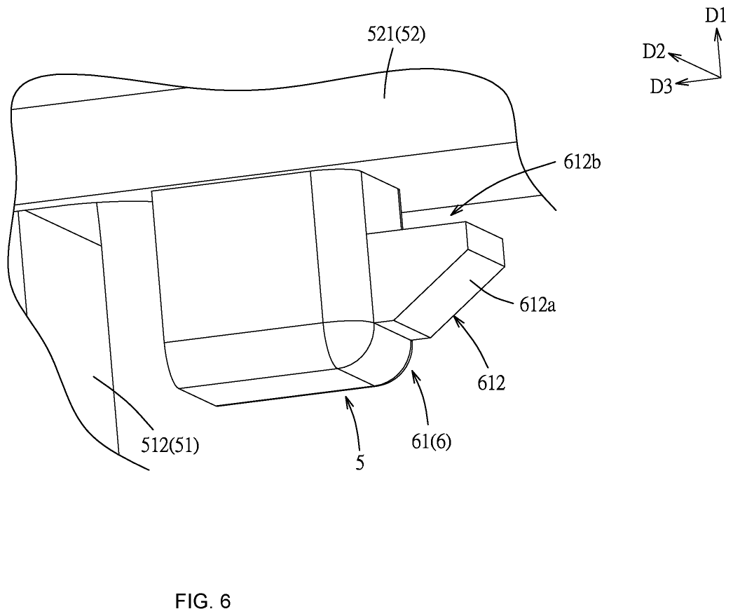

Referring to FIG. 2 to FIG. 6, the first latching construction 61 is provided between the light guide member 5 and the corresponding side plate 14 which extends from the bottom wall 12 of the lower shell 1b. The first latching construction 61 includes a supporting plate 611 and a first latching block 612. The supporting plate 611 is a plate tab which integrally extends out of the corresponding side plate 14 along the left-right direction D2 and is positioned at the outer side of the correspond side wall 13, a plate surface of the supporting plate 611 faces up and is substantially perpendicular to the side plate 14, the supporting plate 611 has an opened hole 611a which is toward the front.

The first latching block 612 is constructed on the light guide member 5, and the first latching block 612 is formed to extend downwardly from one of the plurality of first connecting rods 521. The first latching block 612 has a lower latching block 612a and a latching groove 612bwhich is constituted by the lower latching block 612a and the first connecting rod 521, is positioned between the lower latching block 612a and the first connecting rod 521 and is opened toward the rear. The first latching block 612 is capable of downwardly passing through the opened hole 61 la of the supporting plate 611, so that the latching groove 612b of the first latching block 612 is capable of being pushed rearwardly and latching over the supporting plate 611. Moreover, a left side and a right side of the opened hole 61 la of the supporting plate 611 is capable of limiting movement of the first latching block 612 in the left-right direction D2.

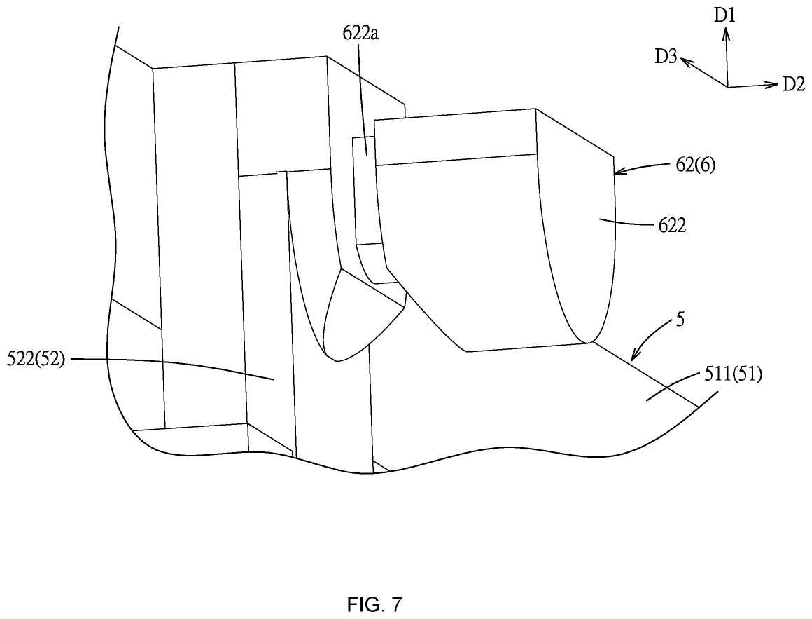

Referring to FIG. 2 to FIG. 4 and FIG. 7, the second latching construction 62 is provided between the light guide member 5 and the top wall 11 of the upper shell la. The second latching construction 62 includes a supporting protrude piece 621 and a second latching block 622. The supporting protrude piece 621 is integrally constructed out of the top wall 11. Specifically, the supporting protrude piece 621 is positioned to the top wall 11 close to the corresponding side wall 13 and protrudes upwardly from the top wall 11, the supporting protrude piece 621 is a piece which is cut apart from the top wall 11 of the upper shell la and is bent upwardly, and a piece surface of the supporting protrude piece 621 faces a side surface of the upper shell la. The supporting protrude piece 621 has a latching notch 621a which is in form of necking and is opened upwardly.

The second latching block 622 is constructed on the light guide member 5, and the second latching block 622 is formed to extend inwardly from one of the plurality of second connecting rods 522 and extend toward the guiding shield cage 1. The second latching block 622 has a necking portion 622a which corresponds to the latching notch 621a in shape, the necking portion 622a of the second latching block 622 is capable of downwardly squeezing into and snapping in the latching notch 621a of the supporting protrude piece 621.

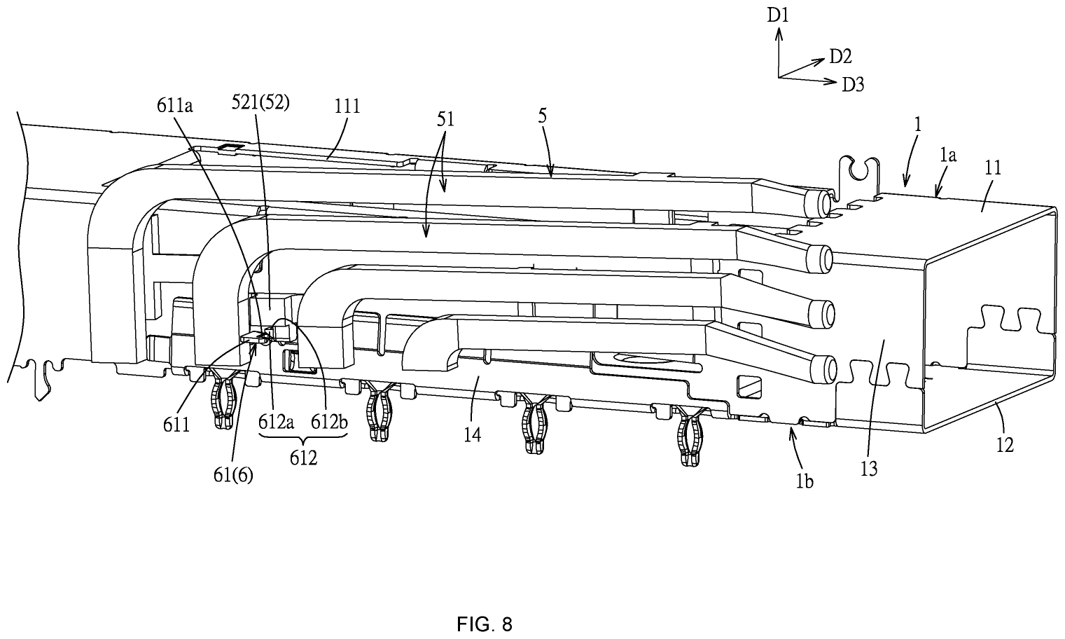

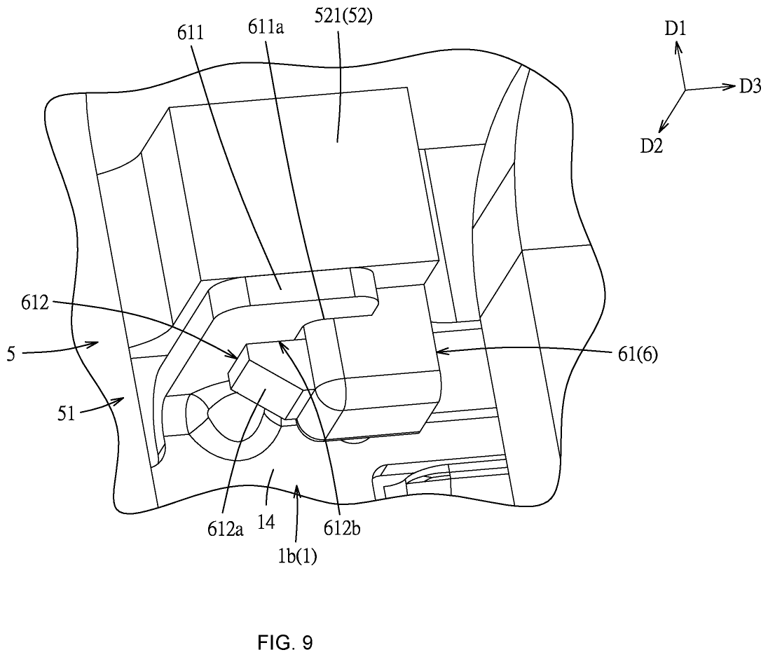

Referring to FIG. 8 and FIG. 9, in a process of assembling operation, firstly the light guide member 5 is made to be oblique in an oblique direction which is slightly toward the rear and the down and the first latching block 612 downwardly inserts into the opened hole 611a of the supporting plate 611, and then the first latching block 612 is pushed rearwardly, so that the latching groove 612b of the first latching block 612 latch over the supporting plate 611.

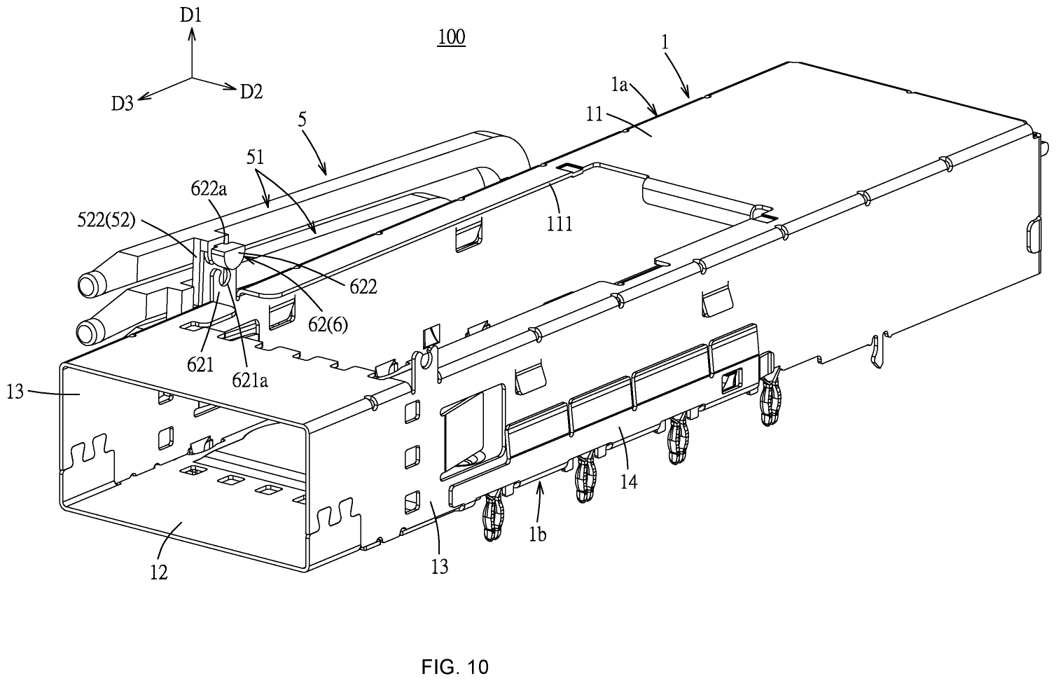

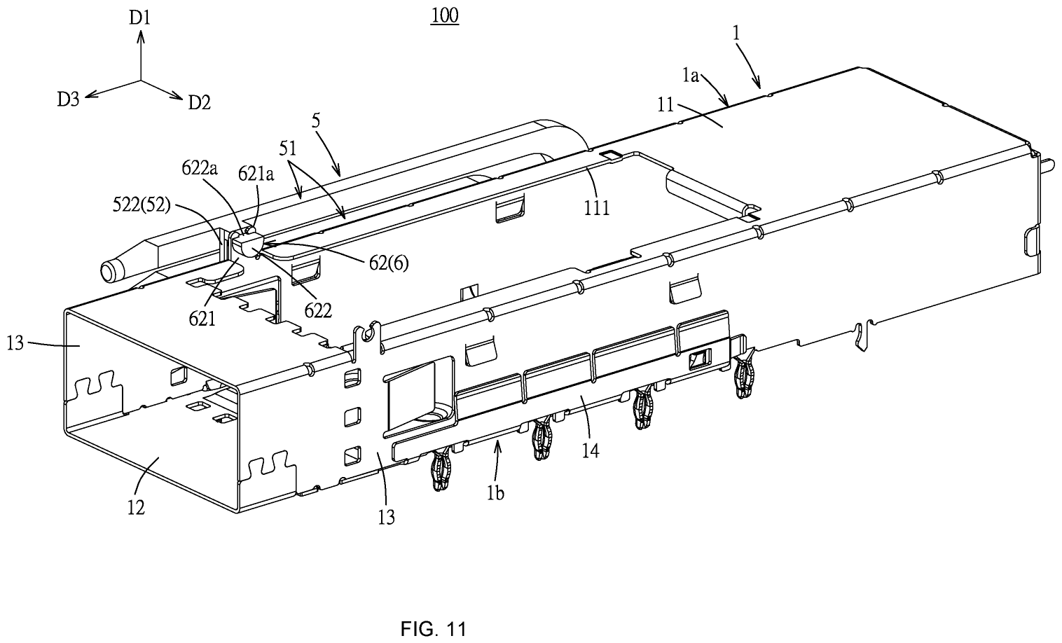

Referring to FIG. 10 and FIG. 11, next the second latching block 622 is pressed downwardly, so that the necking portion 622a of the second latching block 622 snap in the latching notch 621a of the supporting protrude piece 621, at this time, the light guide member 5 returns to a horizontal state from the oblique state and the assembling is completed. In general, the assembling operation of the light guide member 5 basically bases on an operation of “pushing rearwardly” plus “pressing downwardly to snap”, the assembling operation can be completed. Referring to FIG. 1 and FIG. 2, after the assembling operation is completed, the first connecting rod 521 is upwardly supported by the supporting plate 611, the side plate 14 upwardly supports the light guide member 5 via the supporting plate 611 and the first connecting rod 521.

In conclusion, in the present disclosure, the corresponding side plate 14 which extends from the bottom wall 12 is capable of upwardly supporting the light guide member 5, and the light guide member 5 is fixed on the corresponding side plate 14 and the top wall 11 at the same time via the light guide member assembling construction 6, an operation in assembling is easy and the light guiding pipe 51 can be stably and reliably fixed. In addition, the light guiding pipe 51 is provided at the outer side of the corresponding side wall 13 and is capable of being assembled and detached front and rear and up and down, so that a space occupied sideward can be saved. Particularly in an application that a plurality of connector assemblies 100 are arranged side by side, the spaces which are saved sideward are capable of making the guiding shield cages 1 of the plurality of connector assemblies 100 arranged compactly, and it can avoid the corresponding light guiding pipes 51 cannot being detached to remove and assembled after arrangement provision of the guiding shield cages 1 of the plurality of connector assembly 100 are completed. Moreover, the corresponding side wall 13 of the guiding shield cage 1 does not need to be provided with a construction which is used to assemble the light guiding pipe 51, so it does not need to add an aperture in the corresponding side wall 13 for such a construction, therefore it can further increase the electromagnetic interference suppressing effect of the guiding shield cage 1.

However, the above description is only for the embodiment of the present disclosure, and it is not intended to limit the implementing scope of the present disclosure, and the simple equivalent changes and modifications made according to the claims and the contents of the specification are still included in the scope of the present disclosure.

1. A connector assembly, comprising:
a guiding shield cage comprising a top wall, a side wall, a bottom wall, and a supporting plate which extends from the bottom wall and is positioned at an outer side of the side wall;
a light guide member which is provided at the outer side of the side wall of the guiding shield cage and is upwardly supported by the supporting plate; and
a light guide member assembling construction which comprises a first latching construction and a second latching construction, the first latching construction being provided between the light guide member and the supporting plate which extends from the bottom wall, the second latching construction being provided between the light guide member and the top wall.

2. The connector assembly of claim 1, wherein
the guiding shield cage further comprises a side plate which extends from the bottom wall and is positioned at the outer side of the side wall, the supporting plate is a plate tab which integrally extends out of the side plate sideward and is positioned at the outer side of the side wall, a plate surface of the supporting plate faces up;
the first latching construction comprises a first latching block which latches over the supporting plate, the first latching block is constructed on the light guide member;
the second latching construction comprises a supporting protrude piece and a second latching block, the supporting protrude piece is integrally constructed out of the top wall, a piece surface of the supporting protrude piece faces a side surface of the guiding shield cage, the second latching block is constructed on the light guide member, the second latching block snaps to the supporting protrude piece.

3. The connector assembly of claim 2, wherein
the supporting plate has an opened hole,
the first latching block has a latching groove which is opened toward the rear, the first latching block passes through the opened hole of the supporting plate, so that the latching groove is capable of being pushed rearwardly and latching over the supporting plate.

4. The connector assembly of claim 3, wherein
the light guide member comprises a plurality of light guiding pipes and a first connecting rod connected between the light guiding pipes,
the first latching block extends downwardly from the first connecting rod, the first latching block has a lower latching block and the latching groove which is constituted by the lower latching block and the first connecting rod and is positioned between the lower latching block and the first connecting rod,
the first connecting rod is upwardly supported by the supporting plate,
the side plate upwardly supports the light guide member via the supporting plate and the first connecting rod.

5. The connector assembly of claim 4, wherein
the light guide member further comprises a second connecting rod which is connected between the light guiding pipes,
the second latching block extends inwardly from the second connecting rod t and extend toward the guiding shield cage.

6. The connector assembly of any one of claim[s] 2[-5], wherein
the supporting protrude piece has a latching notch which is in form of necking and is opened upwardly,
the second latching block has a necking portion, the necking portion of the second latching block downwardly squeezes into and snaps in the latching notch of the supporting protrude piece.

7. The connector assembly of claim 2, wherein
the guiding shield cage comprises an upper shell and a lower shell,
the upper shell comprises the top wall and two side walls,
the lower shell comprises the bottom wall and two side plates which extends upwardly from two sides of the bottom wall respectively, the two side plates are respectively positioned at outer side surfaces of the two side walls and respectively latch to the two side walls.

8. The connector assembly of claim 7, wherein
the light guide member is provided at the outer side of one corresponding side wall of the two side walls and is upwardly supported by one corresponding side plate of the two side plates,
the light guide member comprises a plurality of light guiding pipes and a plurality of connecting rods,
the plurality of light guiding pipes are sequentially arranged from up to down in a plane which is parallel to the one corresponding side wall and are spaced apart from each other, each light guiding pipe has a forward extending segment which is positioned in the front of the light guiding pipe and extends forwardly, a downward extending segment which is positioned at the rear of the light guiding pipe and extend downwardly, and a bending segment which is positioned between the forward extending segment and the downward extending segment, the plurality of light guiding pipes are therebetween connected with each other via the plurality of connecting rods,
the plurality of connecting rods comprises a first connecting rod which extends front and rear and is connected between the downward extending segments and a second connecting rod which extends up and down and is connected between the forward extending segments,
the first latching block extends downwardly from the first connecting rod,
the second latching block extends inwardly from the second connecting rod and extends toward the guiding shield cage.
